(19) United States
(12) Patent Application Publication
(10) Pub. No.: US 2007/0096800 A1
(43) Pub. Date: May 3, 2007

(54) ANALOG SIGNAL PROCESSING CIRCUIT FOR CCD CAMERA, AND ANALOG SIGNAL PROCESSING METHOD

(75) Inventor: Kouji Yamaguchi, Kyoto (JP)

Correspondence Address: RATNERPRESTIA, P.O. BOX 980, VALLEY FORGE, PA, 19482, US

(73) Assignee: Matsushita Electric Industrial Co., Ltd., Osaka (JP)

(21) Appl. No.: 11/553,514

(22) Filed: Oct. 27, 2006

(30) Foreign Application Priority Data
Oct. 31, 2005 (JP) 2005-316237

(51) Int. Cl. H03F 7/00

(52) U.S. Cl. 330/4.9

(57) ABSTRACT

A switched capacitor amplification circuit configuring an analog signal processing circuit newly includes switch circuits in a second switch circuit section, and a bias circuit in a bias circuit section. Switch circuits in a first switch circuit section are controlled by a pulse wave, are fixedly switched off during a pre-blanking period (PB period), and are switched on/off during a normal period other than the PB period such that the switched capacitor amplification circuit performs a sampling operation. The switch circuits in the second switch circuit section are controlled by a pulse wave, are switched on/off during the PB period such that the switched capacitor amplification circuit performs a sampling operation, and are fixedly switched off during the normal period other than the PB period.

This application is based on Japanese Patent Application No. 2005-316237 filed in Japan on Oct. 31, 2005, the contents of which are hereby incorporated by reference.

### BACKGROUND OF THE INVENTION

1. Field of the Invention

The present invention relates to an analog signal processing circuit in a digital still camera, a video camera, a portable telephone with a camera function, a surveillance camera and the like each using a CCD as an imaging device. In particular, the present invention relates to an analog signal processing circuit for a CCD camera, which is effectively used for preventing operations from being erroneously performed during a pre-blanking period and a normal period immediately after the pre-blanking period, due to an influence of unintentional excessive input signals received during the pre-blanking period.

2. Description of the Related Art

FIG. 3 is a circuit diagram showing a configuration of a conventional analog signal processing circuit for a CCD camera as shown in Japanese Patent Laid-open Publication No. 5-328230 (1993). This analog signal processing circuit for a CCD camera includes a switched capacitor amplification circuit 51, a black level sample/hold circuit 52, and an input DC level circuit 53.

As illustrated in FIG. 3, the switched capacitor amplification circuit 51 includes an operational amplification circuit OP10, switch circuits SW102 to SW112, capacitors C12 to C15, and bias circuits Vref11 to Vref16. The black level sample/hold circuit 52 includes a switch circuit SW21 and a capacitor C21. The input DC level circuit 53 includes a resistor R31 and a bias circuit Vref30. Herein, a switch circuit SW10 is serially connected to an input terminal 54.

Next, description will be given of operations of the conventional analog signal processing circuit for a CCD camera, configured as described above. The analog signal processing circuit for a CCD camera is a circuit for extracting only a desired signal component from an input signal and amplifying the extracted signal component.

With respect to an input signal wave shown in FIG. 4, the black level sample/hold circuit 52 is switched on during a HIGH period of a pulse wave A for controlling a switch circuit to thereby sample/hold a reference level (black level) of an input signal.

With respect to the input signal wave shown in FIG. 4, also, the switch circuits SW102, SW103, SW105, SW106, SW107, SW108, SW111 and SW112 are switched on during a HIGH period of a pulse wave B of a control signal shown in FIG. 4; thus, the switched capacitor amplification circuit 51 performs a sampling operation. In addition, the switch circuits SW104, SW109 and SW110 are switched on during a HIGH period of a pulse wave C of a control signal shown FIG. 4; thus, the switched capacitor amplification circuit 51 performs an amplifying operation.

Wave forms VOP and VON shown in FIG. 4 are output waves of the analog signal processing circuit for a CCD camera, that amplifies only a desired signal component from an input signal wave through a sequence of the sampling operation and the amplifying operation by the switched capacitor amplification circuit 51.

In the analog signal processing circuit, the switch circuit SW10 serially connected to the input terminal 54 shown in FIG. 3 is switched off during a pre-blanking period. Thus, it is possible to realize an analog signal processing circuit for a CCD camera, capable of preventing operations from being erroneously performed during a pre-blanking period and during a normal period immediately after the pre-blanking period, due to an influence of unintentional excessive input signals received during the pre-blanking period.

In the analog signal processing circuit for a CCD camera, configured as described above, however, the switch circuit SW10 is serially connected to the input terminal 54 as shown in FIG. 3 for the purpose of preventing operations from being erroneously performed during a pre-blanking period and during a normal period immediately after the pre-blanking period, due to an influence of unintentional excessive input signals received during the pre-blanking period.

Consequently, a signal received during the normal period other than the pre-blanking period is degraded in signal amplitude due to resistance division between a resistance component of the switch circuit SW10 and the resistor R31 of the input DC level circuit 53. Further, the resistance component of the switch circuit SW10 causes a noise source; thus, noise is also deteriorated.

### SUMMARY OF THE INVENTION

The present invention is directed to solve the problems in the conventional art. An object of the present invention is to provide an analog signal processing circuit for a CCD camera, capable of preventing operations from being erroneously performed during a pre-blanking period and during a normal period immediately after the pre-blanking period without degradation in signal amplitude and deterioration in noise amount even in the normal period other than the pre-blanking period.

In order to achieve this object, an analog signal processing circuit for a CCD camera according to the present invention includes a switched capacitor amplification circuit performing a sampling operation and an amplifying operation on a wave form of a received input signal. Herein, the switched capacitor amplification circuit includes: a first switch circuit section switched on/off during a normal period such that the switched capacitor amplification circuit performs the sampling operation and fixedly switched off during a pre-blanking period between normal periods; and a second switch circuit section arranged subsequent to the first switch circuit section from an input side, fixedly switched off during the normal period, and switched on/off during the pre-blanking period such that the switched capacitor amplification circuit performs the sampling operation.

With this configuration, two switch circuits are provided. During a normal period, one of the switch circuits is switched on/off and the other one of the switch circuits is fixedly switched off; thus, a sampling operation is performed. During a pre-blanking period, one of the switch circuits is fixedly switched off and the other one of the switch circuits is switched on/off; thus, the sampling operation is performed. By appropriately using a switch circuit for use in a sampling operation between a normal period and a pre-blanking period, it is possible to prevent operations from being erroneously performed during a pre-blanking period and during a normal period immediately after the pre-blanking period, due to an influence of unintentional excessive input signals received during the pre-blanking period, without degradation in signal amplitude and deterioration in noise amount even in the normal period.

For a CCD camera, an analog signal processing circuit is required for preventing operations from being erroneously performed during a pre-blanking period and during a normal period immediately after the pre-blanking period, due to an influence of unintentional excessive input signals received during the pre-blanking period.

The present invention has an effect of preventing operations from being erroneously performed during a pre-blanking period and during a normal period immediately after the pre-blanking period without degradation in signal amplitude and deterioration in noise amount even in the normal period other than the pre-blanking period.

### BRIEF DESCRIPTION OF THE DRAWINGS

These objects and other objects, features, aspects and advantages of the present invention will become more apparent from the following detailed description of the present invention when taken in conjunction with the accompanying drawings:

FIG. 1 is a circuit diagram showing an analog signal processing circuit for a CCD camera according to the present invention;

FIG. 2 is a timing chart showing operations of the analog signal processing circuit for a CCD camera upon reception of excessive input signals;

FIG. 3 is a circuit diagram showing a conventional analog signal processing circuit for a CCD camera; and

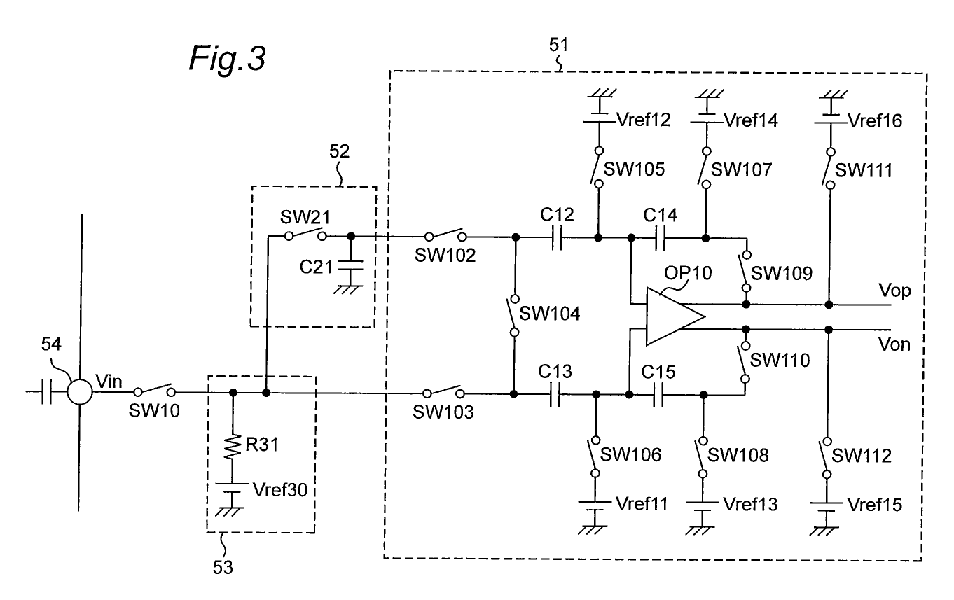

FIG. 4 is a timing chart showing operations of the conventional analog signal processing circuit for a CCD camera.

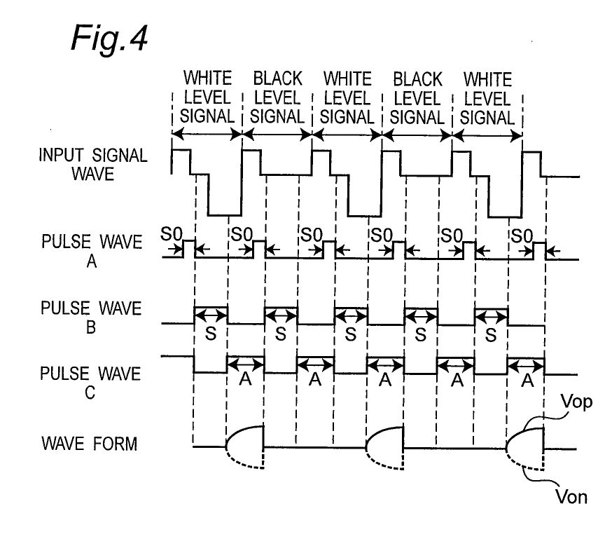

### DESCRIPTION OF THE PREFERRED EMBODIMENTS

Hereinafter, specific description will be given of a preferred embodiment of the present invention with reference to the drawings. In the drawings, substantially the same components are denoted by the same symbols.

### First Embodiment

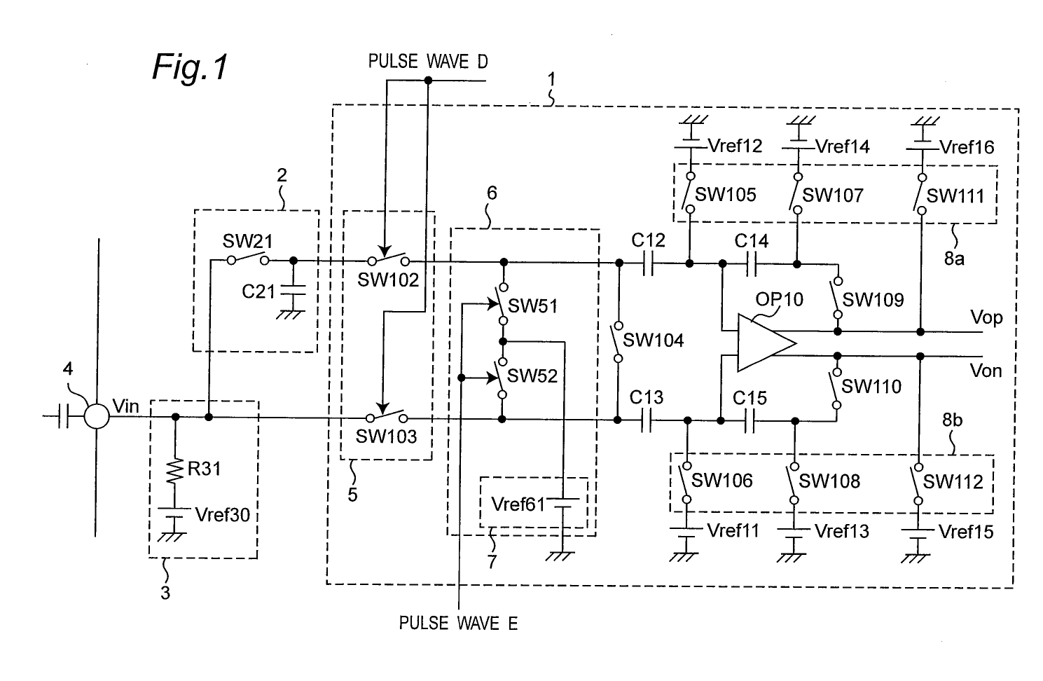

FIG. 1 is a circuit diagram showing a configuration of an analog signal processing circuit for a CCD camera according to a first embodiment of the present invention. The analog signal processing circuit for a CCD camera includes a switched capacitor amplification circuit 1, a black level sample/hold circuit 2 and an input DC level circuit 3.

As illustrated in FIG. 1, the switched capacitor amplification circuit 1 includes an operational amplification circuit OP10, a first switch circuit section 5 (SW102, SW103), sampling switch circuit sections 8a and 8b (SW105 to SW108, SW111, SW112), amplifying switch circuits SW104, SW109 and SW110, capacitors C12 to C15, bias circuits Vref11 to Vref16, a second switch circuit section 6 having switch circuits SW51 and SW52, and a bias circuit section 7 having a bias circuit Vref61. Herein, the switch circuits SW51 and SW52 in the second switch circuit section 6 and the bias circuit Vref61 in the bias circuit section 7 are newly provided in this embodiment.

The black level sample/hold circuit 2 includes a switch circuit SW21 and a capacitor C21. The input DC level circuit 3 includes a resistor R31 and a bias circuit Vref30.

Hereinafter, description will be given of operations of the analog signal processing circuit for a CCD camera according to this embodiment, configured as described above. The analog signal processing circuit for a CCD camera extracts only a desired signal component from an input signal and amplifies the extracted signal component in a basic operation.

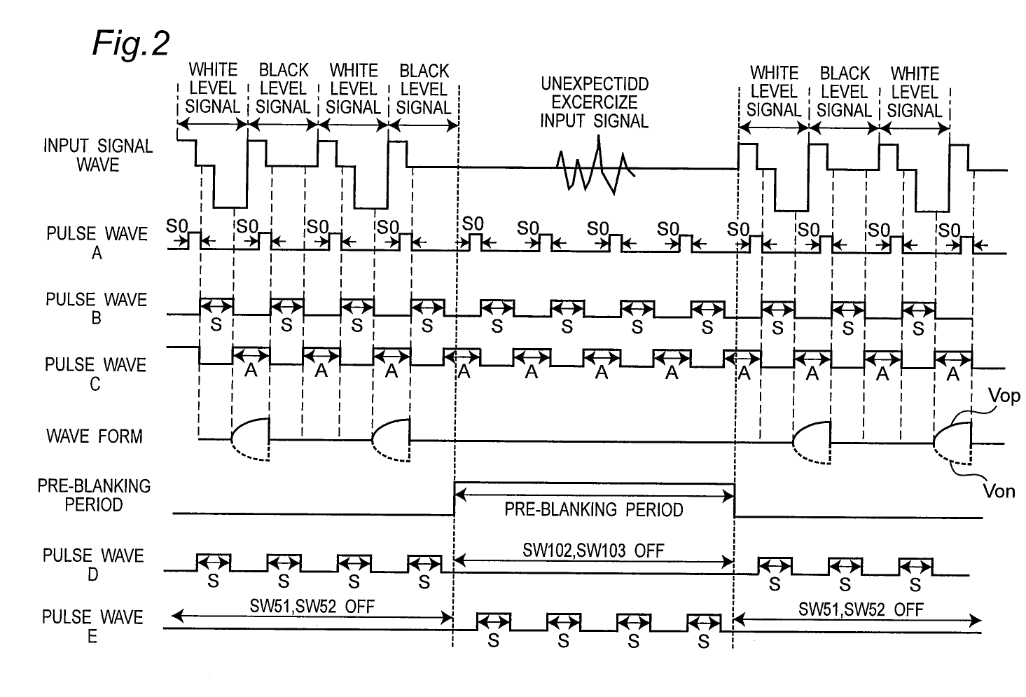

Hereinafter, description will be given of control of the respective switch circuits and signal processing operations during a normal period and a pre-blanking period with reference to FIGS. 1 and 2.

First, description will be given of signal processing operations during the normal period.

(a) With respect to an input signal wave shown in FIG. 2, the black level sample/hold circuit 2 is switched on during a HIGH period of a pulse wave A for controlling a switch circuit to thereby sample/hold a reference level (black level) of an input signal.

(b) With respect to the input signal wave shown in FIG. 2, also, the switch circuits SW102 and SW103 in the first switch section 5, and the switch circuits SW105, SW106, SW107, SW108, SW111 and SW112 in the sampling switch circuit sections 8a and 8b are switched on during a HIGH period of a pulse wave B of a control signal shown in FIG. 2; thus, the switched capacitor amplification circuit 1 performs a sampling operation. In addition, switch circuits SW104, SW109 and SW110 are switched on during a HIGH period of a pulse wave C of a control signal shown in FIG. 2; thus, the switched capacitor amplification circuit 1 performs an amplifying operation.

Next, description will be given of operations during the pre-blanking period.

(c) In this embodiment, as shown in FIG. 2, the switch circuits SW102 and SW103 in the first switch circuit section 5 shown in FIG. 1 are controlled by a pulse wave D outputted from a controller (not shown) so as to be fixedly switched off during the pre-blanking period. As described above, during the normal period other than the pre-blanking period, the switch circuits SW102 and SW103 in the first switch circuit section 5 are switched on/off; thus, the sampling operation is performed.

(d) Then, the switch circuits SW51 and SW52 shown in FIG. 1 are controlled by a pulse wave E outputted from the controller (not shown). The switch circuits SW51 and SW52 are switched on/off during the pre-blanking period; thus, the switched capacitor amplification circuit 1 performs the sampling operation. However, the switch circuits SW51 and SW52 are fixedly switched off during the normal period other than the pre-blanking period.

In the analog signal processing circuit for a CCD camera according to this embodiment, as described above, the switched capacitor amplification circuit 1 newly includes the switch circuits SW51 and SW52 in the second switch circuit section 6, and the bias circuit Vref61 in the bias circuit section 7. Further, the switch circuits SW102 and SW103 in the first switch circuit section 5 and the switch circuits SW51 and SW52 in the second switch circuit section 6 are controlled by the pulse waves D and E shown in FIG. 2, respectively. The switched capacitor amplification circuit 1 performs the sampling operation while switching between the two switch circuit sections 5 and 6 during the normal period and the pre-blanking period. Thus, it is possible to prevent operations from being erroneously performed during the pre-blanking period and the normal period immediately after the pre-blanking period, due to an influence of unintentional excessive input signals received during the pre-blanking period.

The analog signal processing circuit for a CCD camera according to this embodiment can prevent operations from being erroneously performed during the pre-blanking period and during the normal period immediately after the pre-blanking period without degradation in signal amplitude and deterioration in noise amount even in the normal period other than the pre-blanking period.

The analog signal processing circuit for a CCD camera according to the present invention can prevent operations from being erroneously performed during the pre-blanking period and during the normal period immediately after the pre-blanking period without degradation in signal amplitude and deterioration in noise amount even in the normal period other than the pre-blanking period. Therefore, the analog signal processing circuit for a CCD camera according to the present invention is effective as an analog signal processing circuit capable of preventing erroneous operations.

Although the present invention has been described in connection with the preferred embodiments thereof with reference to the accompanying drawings, it is to be noted that various changes and modifications are apparent to those skilled in the art. Such changes and modifications are to be understood as included within the scope of the present invention as defined by the appended claims, unless they depart therefrom.

What is claimed is:

1. An analog signal processing circuit comprising a switched capacitor amplification circuit performing a sampling operation and an amplifying operation on a wave form of a received input signal,
wherein the switched capacitor amplification circuit includes:
a first switch circuit section switched on/off during a normal period such that the switched capacitor amplification circuit performs the sampling operation and fixedly switched off during a pre-blanking period between normal periods; and
a second switch circuit section arranged subsequent to the first switch circuit section from an input side, fixedly switched off during the normal period, and switched on/off during the pre-blanking period such that the switched capacitor amplification circuit performs the sampling operation.

2. The analog signal processing circuit according to claim 1, wherein the second switch circuit section includes a bias circuit section.

3. The analog signal processing circuit according to claim 1, wherein the analog signal processing circuit further comprises a black level sample/hold circuit sampling/holding a reference level of the input signal.

4. The analog signal processing circuit according to claim 1, wherein the analog signal processing circuit further comprises an input DC level circuit.

5. An analog signal processing method by an analog signal processing circuit including a first switch circuit section and a second switch circuit section arranged sequentially from an input side and performing a sampling operation and an amplifying operation on a wave form of a received input signal, the method comprising:
switching on/off the first switch circuit section while fixedly switching off the second switch circuit section during a normal period such that the switched capacitor amplification circuit performs the sampling operation and the amplifying operation; and
switching on/off the second switch circuit section while fixedly switching off the first switch circuit section during a pre-blanking period between normal periods such that the switched capacitor amplification circuit performs the sampling operation and the amplifying operation.
